(19) United States
(12) Patent Application Publication
(10) Pub. No.: US 2016/0062513 A1
(43) Pub. Date: Mar. 3, 2016

(54) CAPACITIVE TOUCH SWITCH WITH FALSE TRIGGER PROTECTION

(71) Applicant: Gentex Corporation, Zeeland, MI (US)

(72) Inventor: Robert R. Turnbull, Holland, MI (US)

(21) Appl. No.: 14/837,093

(22) Filed: Aug. 27, 2015

Related U.S. Application Data
(60) Provisional application No. 62/043,568, filed on Aug. 29, 2014.

(51) Int. Cl. G06F 3/044; G01B 7/14; G06F 3/041; G01R 27/26

(52) U.S. Cl. CPC G06F 3/044; G01R 27/2605; G01B 7/14; G06F 3/041; G06F 3/0418; G06F 2203/04103; G06F 2203/04112

(57) ABSTRACT

An electronics module proximate an exterior surface of a vehicle is disclosed. The module comprises a housing configured for mounting to an interior surface of the vehicle. An electronic circuit is enclosed in the housing. The electronic circuit comprises a proximity sensor and a sensor guard. The proximity sensor is configured to detect an object proximate the housing. The sensor guard is disposed between the interior surface and the proximity sensor and configured to limit a detection by the proximity sensor of an input originating from the exterior surface of a vehicle.

### CROSS REFERENCE TO RELATED APPLICATION

This application claims priority of U.S. Provisional Application No. 62/043,568, filed Aug. 29, 2014, and the entirety of which is incorporated by reference herein.

### BACKGROUND OF THE DISCLOSURE

The present disclosure generally relates to a proximity sensor for a vehicle, and more specifically relates to an electronics module for a vehicle including proximity sensor.

### SUMMARY OF THE PRESENT DISCLOSURE

According to one aspect of the present disclosure, an electronics module proximate an exterior surface of a vehicle is disclosed. The module comprises a housing configured for mounting to an interior surface of the vehicle. An electronic circuit is enclosed in the housing. The electronic circuit comprises a proximity sensor and a sensor guard. The proximity sensor is configured to detect an object proximate the housing. The sensor guard is disposed between the interior surface and the proximity sensor and configured to limit a detection by the proximity sensor of an input originating from the exterior surface of a vehicle.

According to another aspect of the present disclosure, an electronic circuit for mounting to an inside surface of a windshield of a vehicle is disclosed. The electronic circuit is configured to control a vehicle accessory and comprises a capacitive sensor, a sensor guard, and a processor. The capacitive sensor is configured to detect an object in proximity thereto. The sensor guard is disposed between the windshield and the capacitive sensor, and the processor is in communication with the capacitive sensor. The sensor guard is configured to limit a false detection by the processor due to an input originating from an outside surface of the windshield.

According to yet another aspect of the present disclosure, a trainable transmitter module for a vehicle is disclosed. The housing is configured to enclose an electronic circuit and is configured for mounting to an inside surface of a windshield of the vehicle. The electronic circuit comprises a user interface including a capacitive touch switch having a touch electrode for sensing a proximity of a user's finger or hand. A guard electrode is positioned between the windshield and at least a portion of the touch electrode. The guard electrode is configured to reduce a possibility that the touch electrode is falsely triggered by an input originating from an outside surface of the windshield.

The electronic circuit further comprises a backlight for illuminating indicia on the user interface. A processor is coupled to the touch electrode, the guard electrode, and the backlight. The processor is configured to detect a voltage change on the touch electrode caused by the user's finger or hand to activate the backlight. The processor may activate the backlight in response to the voltage change on the touch electrode. A trainable transmitter circuitry is coupled to the processor and the processor is configured to control the trainable transmitter circuitry in response to user activation through the user interface.

These and other aspects, objects, and features of the present disclosure will be understood and appreciated by those skilled in the art upon studying the following specification, claims, and appended drawings. It will also be understood that features of each embodiment disclosed herein may be used in conjunction with, or as a replacement for, features of the other embodiments.

### BRIEF DESCRIPTION OF THE DRAWINGS

In the drawings:

FIG. 1 is a perspective view of an electronics module according to one embodiment as installed on a windshield of a vehicle;

FIG. 2 is a perspective view of an electronics module according to another embodiment;

FIG. 3A is an electrical diagram in block form of an electronic circuit including a proximity sensor circuit according to one implementation;

FIG. 3B is an electrical diagram in block form of an electronic circuit including a proximity sensor circuit according to an alternate implementation;

FIG. 4 is a block diagram from the perspective of a cross sectional view of an electronics module installed on a windshield; and

FIG. 5 is a top plan view of a printed circuit board on which the electronic circuit of FIG. 3A or 3B is disposed.

### DETAILED DESCRIPTION OF THE EMBODIMENTS

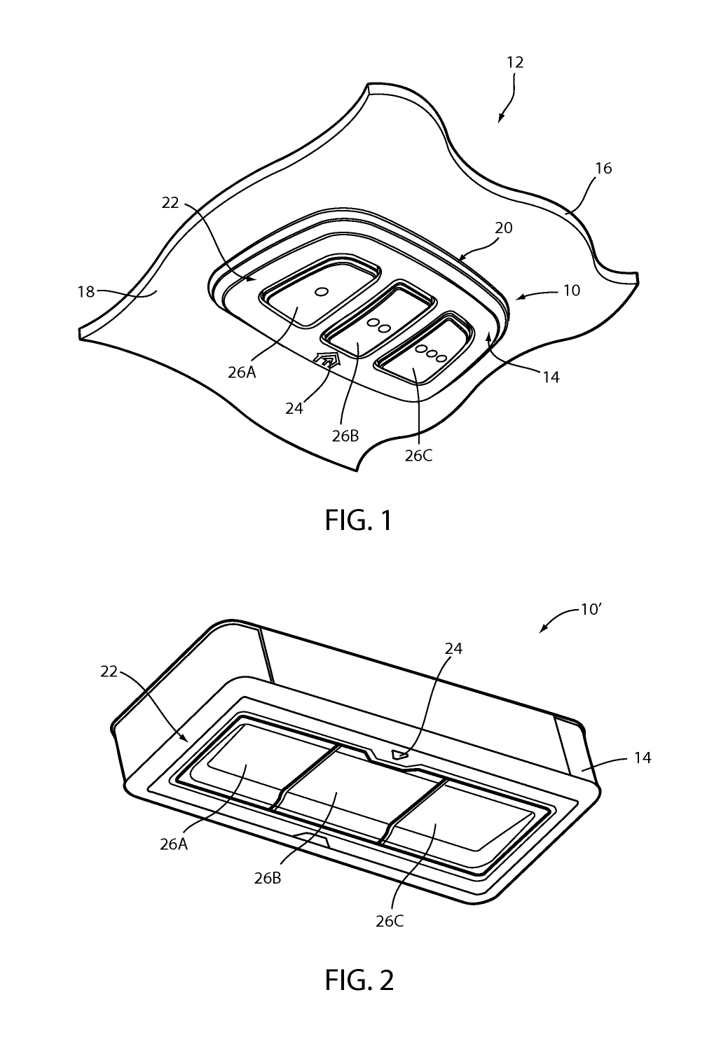

For purposes of description herein, the terms “upper,” “lower,” “right,” “left,” “rear,” “front,” “vertical,” “horizontal,” and derivatives thereof shall relate to the disclosure as oriented in FIG. 1. However, it is to be understood that the disclosure may assume various alternative orientations, except where expressly specified to the contrary. It is also to be understood that the specific devices and processes illustrated in the attached drawings and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

Electronics modules of vehicles sometimes include one or more proximity sensors as user actuated buttons in a user interface. One electronics module that may include such proximity sensors is a trainable transmitter, such as the HOMELINK® trainable transmitter available from Gentex Corporation of Zeeland, Mich. Such trainable transmitters have been previously available as factory-installed, in-vehicle components. Such trainable transmitters are integrated into a vehicle, such as by being generally permanently mounted on the headliner, a windshield visor, a rearview mirror, or the like. Further, the trainable transmitters can communicate directly with a garage door opener and can be in the form of a trainable remote garage door opener that can learn the signal protocols of a remote transmitter that comes with such a garage door opener and later transmit a signal having those protocols. As such, they can accommodate many different garage door opener protocols using multiple codes and signaling frequencies to provide integrated vehicle door access. In addition, the HOMELINK® trainable transmitters are capable of remotely controlling various electrical appliances, such as lights, gates, and security systems.

An electronics module is herein described that may be mounted to the inside of the vehicle windshield such that a proximity sensor included in the electronics module is located in close proximity to the windshield. The inventor has recognized a problem with such an installation insofar as the proximity sensor may be inadvertently triggered in response to an input originating from an outside surface of the windshield. For example, the proximity sensor may correspond to a capacitive touch switch having a capacitive touch electrode. The capacitive touch electrode may be falsely triggered by an input originating outside the windshield.

The object may correspond to any object, body, or matter proximate an exterior surface of the windshield particularly in a region proximate the proximity sensor. The object may correspond to various objects or substances that may be in proximity with or contact the windshield. For example, contaminants (e.g. biological material), rain, or snow on the outside of the windshield may cause the proximity sensor to falsely trigger a proximity detection. Additionally, the windshield wipers when passing in proximity of the proximity sensor may trigger the proximity detection. The false detection may be particularly problematic when using a proximity sensor comprising a capacitive touch switch. This may be due to a high level of sensitivity of some capacitive touch switches to various detections that may not correspond to the detection of a user's hand or finger.

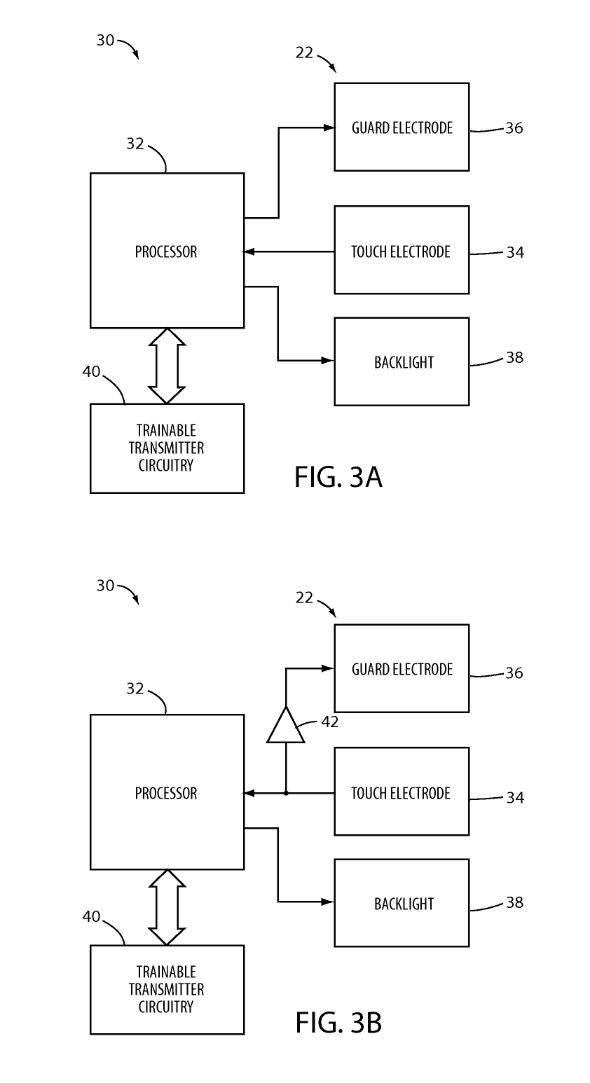

Referring to FIG. 1, reference numeral 10 generally designates an electronics module for installation into a vehicle 12. The module 10 may be a trainable transmitter module, such as a HOMELINK® trainable transmitter, and includes a housing 14 disposable against a windshield 16 of the vehicle 12 along an interior surface 18 thereof. The housing 14 encloses electronic circuitry 30 such as that shown in FIGS. 3A and 3B. A user interface 22 is provided that includes one or more buttons 26A, 26B, 26C that are exposed at a side of the housing 14 and are coupled to the electronic circuitry. A backlit indicia 24 may also be provided in the user interface 22. The module 10 further may include a mounting element 20 that may be glued or otherwise secured to the windshield 16 for coupling the housing 14 to the windshield 16. Alternatively, the housing 14 may be configured to be directly secured to the windshield 16.

FIG. 2 shows an additional embodiment for a windshield-mounted electronics module 10′. The configuration shown in FIG. 2 has features similar to those discussed in reference to FIG. 1. As such, corresponding features are like numbered for clarity. Though specific embodiments are shown in FIGS. 1 and 2, an electronics module may correspond to various combinations and/or variations of the disclosed embodiments without departing from the spirit of the disclosure.

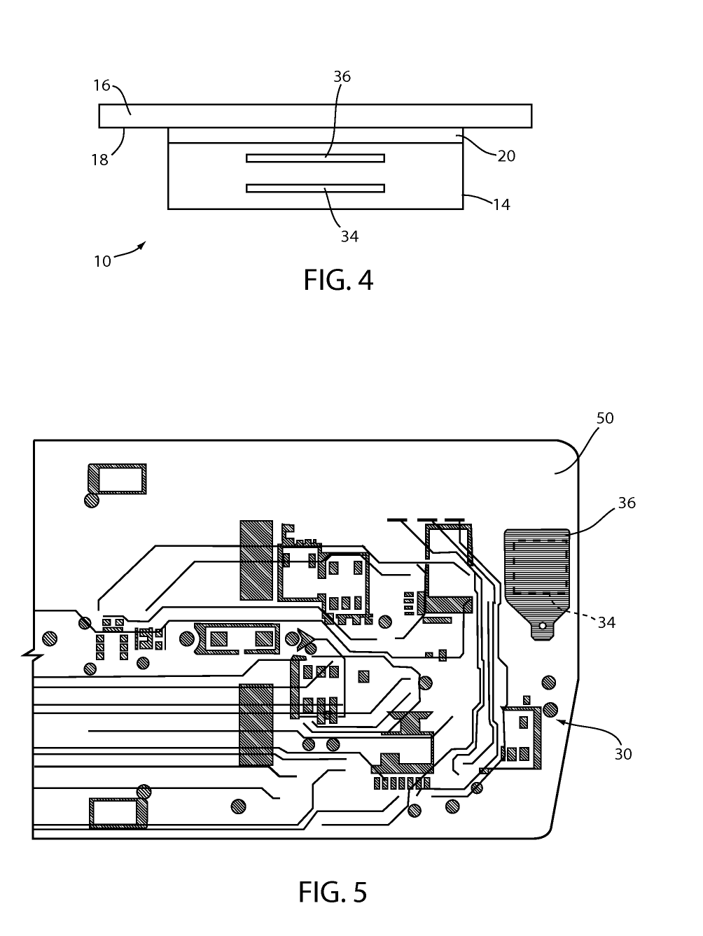

Referring now to FIGS. 3A and 3B, electronic circuitry 30 of the electronics module 10 may include a user interface 22 including a proximity sensor. As previously discussed, the capacitive sensor may correspond to a capacitive touch switch having a touch electrode 34 for sensing proximity of a user's finger or hand. The electronic circuitry 30 may further comprise a sensor guard configured to limit the proximity sensor from detect inputs from outside the windshield. The sensor guard may correspond to a guard electrode 36 positioned between the windshield 16 and at least a portion of the touch electrode 34 as shown in FIG. 4. The guard electrode 36 is configured to reduce a possibility that touch electrode 34 is falsely triggered by noise at an outside surface of the windshield 16, such as that caused by rain or the vehicle's windshield wipers.

Though discussed in reference to the capacitive sensor, the proximity sensor may correspond to various forms of sensors that may be utilized to detect the proximity of an object. For example, the proximity sensor may correspond to a resistive, inductive, capacitive or a variety of sensors or combinations thereof that may be utilized to detect an object proximate the housing 14. Each of the sensors may be utilized to accomplish different sensory functions and may be incorporated in the housing to provide various functions. In an exemplary embodiment, the proximity sensor is configured to detect the object in the form of a hand or arm of a passenger of the vehicle proximate the user interface 22 of the housing 14.

The user interface 22 may further include a backlight 38 for illuminating an indicia 24 (FIGS. 1 and 2). Such indicia 24 may be an indicator light, an icon, or a plurality of indicator lights or icons that may correspond to certain functions or buttons, such as buttons 26A, 26B, 26C. Buttons 26A, 26B, 26C may correspond to any form of electrical of electro-mechanical switches or buttons. For example, the buttons 26A, 26B, 26C may correspond to mechanical push buttons, capacitive touch switches, or any other form of switches. The capacitive touch switches may be formed using touch electrodes 34 and guard electrodes 36 as discussed herein. Thus, multiple touch electrodes 34 may be provided. For example, one touch electrode 34 may be provided to detect a proximity of a user's hand such that indicia 24 may be illuminated in response to the detection of the user's hand in proximity. This functionality may improve the visibility of the buttons 26A, 26B, 26C such that an operator may selectively activate a specific button of the buttons 26A, 26B, 26C one of the buttons via pressing or lightly touching the button.

Electronic circuit 30 may further include a processor 32 communicatively coupled to the touch electrode 34, the guard electrode 36, and the backlight 38. The processor 32 may be configured to detect a voltage change on the touch electrode 34 in response to a detection of a proximity of a finger or hand. In response to the detection of the voltage change from the touch electrode 34, the processor 32 may activate the backlight 38.

The guard electrode 36 may be implemented in a relatively simple form as a ground plane beneath the touch electrode 34. While this implementation may be effective in reducing signals on the outside of the windshield 16 it may also add capacitance between the ground plane and the touch electrode 34. This may reduce the sensitivity of the touch electrode 34 in the desired direction. While this may be acceptable in some situations, in other cases the sensitivity loss may be too great. By perforating the ground plane a compromise between sensitivity in the desired and undesired directions may be affected. Increasing the surface area of the perforations or the effective cutout in the ground plane may reduce the shielding effect in the undesired direction but will also increase sensitivity in the desired direction.

In some embodiments, the guard electrode may correspond to an actively driven guard electrode 36 as shown in FIGS. 3A and 3B. The guard drive voltage should match the amplitude and phase of the voltage on the touch electrode 34; this may be accomplished by generating a signal that duplicates the signal on the touch electrode 34 (FIG. 3A) or by actively buffering the touch electrode signal to drive the guard electrode 36 with a unity gain amplifier 42 (FIG. 3B). In this way, the effect of the capacitance between the touch electrode 34 and guard electrode 36 is minimized. The processor 32 further may be configured to provide a voltage on the guard electrode 36 so as to match any voltage changes on touch electrode 34 and the guard electrode 36. By matching the voltage changes, the processor may distinguish between a proximity of a user's hand and noise coming from the outside of windshield 16. The processor 32 may be implemented using part number PIC16LF1829, available from Microchip Technology Inc. of Chandler, Ariz., which includes input pins to receive signals for touch electrodes and output pins output control signals to the guard electrode.

Electronic circuit 30 may include a vehicle accessory circuit, for example trainable transmitter circuitry 40 coupled to processor 32. The processor 32 may be configured to control the trainable transmitter circuitry 40 in response to a user activation of one or more of the buttons 26A, 26B, 26C through user interface 22. Although the vehicle accessory circuit is described herein as a trainable transmitter circuit, it will be appreciated that the vehicle accessory circuit may be any other form of vehicle accessory, such as a navigation accessory, a radar detector, a tollbooth transceiver, etc.

As shown in FIG. 4, with the housing 14 of the module 10 mounted to an inside surface 18 of windshield 16 by a mounting element 20, guard electrode 36 is positioned between the windshield 16 and at least a portion of the touch electrode 34. In general, the size of the guard electrode 36 is commensurate with the size of the touch electrode 34 so that guard electrode 36 extends between windshield 16 and all portions of touch electrode 34. However, if guard electrode 36 does not extend between windshield 16 and all portions of touch electrode 34, but only a portion of touch electrode 34, guard electrode 36 will still at least reduce the likelihood of a false trigger due to an input or noise originating from outside the windshield 16.

FIG. 5 demonstrates a portion of a printed circuit board 50 on which electronic circuitry 30 is provided. As shown, the guard electrode 36 may only extend over a portion of the circuit board 50. The portion of the circuit board 50 over which the guard electrode extends may correspond to the portion of the circuit board where the touch electrode 34 is disposed. The touch electrode 34 may be disposed on a top surface of circuit board 50 and may be connected to the circuit board 50 by a flat spring (not shown). A ground plane (not shown) may be provided on the top surface of the printed circuit board 50. The ground plane may extend across most of the top surface of the circuit board 50, but may have a cut-out area corresponding to the touch electrode 34 and/or guard electrode 36.

The electronics module 10 may receive power from the vehicle's power system or may include a battery and, optionally, a solar cell. In the various configurations described herein, the disclosure provides for an electronics module disposed on a windshield of a vehicle. The electronics module comprises a proximity sensor that is resistant to inputs or noise corresponding to objects located outside the windshield and proximate the proximity sensor. In this configuration, the proximity sensor may limit the unwanted detection of objects outside the vehicle. In this way, the disclosure may provide for a touch electrode configured to prevent false triggers and/or activations related to undesired detections.

It will be understood by one having ordinary skill in the art that construction of the described disclosure and other components is not limited to any specific material. Other exemplary embodiments of the disclosure disclosed herein may be formed from a wide variety of materials, unless described otherwise herein.

For purposes of this disclosure, the term “coupled” (in all of its forms, couple, coupling, coupled, etc.) generally means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components. Such joining may be permanent in nature or may be removable or releasable in nature unless otherwise stated.

It is also important to note that the construction and arrangement of the elements of the disclosure as shown in the exemplary embodiments is illustrative only. Although only a few embodiments of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, the bezel of the module disclosed herein may take on a variety of shapes and could be flat, curved, bent, etc. Further, elements shown as integrally formed may be constructed of multiple parts, elements shown as multiple parts may be integrally formed, the operation of the interfaces may be reversed or otherwise varied, the length or width of the structures and/or members or connector or other elements of the system may be varied, or the nature or numeral of adjustment positions provided between the elements may be varied. It should be noted that the elements and/or assemblies of the system may be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

It will be understood that any described processes or steps within described processes may be combined with other disclosed processes or steps to form structures within the scope of the present disclosure. The exemplary structures and processes disclosed herein are for illustrative purposes and are not to be construed as limiting.

It is also to be understood that variations and modifications can be made on the aforementioned structures and methods without departing from the concepts of the present disclosure, and further it is to be understood that such concepts are intended to be covered by the following claims unless these claims by their language expressly state otherwise.

What is claimed is:

1. An electronics module proximate an exterior surface of a vehicle, the module comprising:
a housing configured for mounting to an interior surface of the vehicle; and
an electronic circuit enclosed in the housing, the electronic circuit comprising:
a proximity sensor configured to detect an object proximate the housing;
a sensor guard disposed between the interior surface and the proximity sensor, wherein the sensor guard is configured to limit a detection by the proximity sensor of an input originating from the exterior surface of a vehicle.

2. The electronics module according to claim 1, wherein the proximity sensor corresponds to a capacitive proximity sensor.

3. The electronics module according to claim 2, wherein the capacitive proximity sensor comprises a touch electrode configured to detect the object.

4. The electronics module according to claim 1, wherein the object corresponds to a portion of a body of a passenger of the vehicle.

5. The electronics module according to claim 1, wherein the sensor guard corresponds to a guard electrode.

6. The electronics module according to claim 5, wherein the guard electrode is configured to reduce a possibility that the touch electrode is falsely triggered by the input.

7. The electronics module according to claim 1, wherein the guard electrode is configured is actively driven in response to a signal received from the proximity sensor.

8. The electronics module according to claim 1, further comprising a user interface having at least one indicia configured to illuminate.

9. The electronics module according to claim 8, wherein the electronics module is configured to illuminate the at least one indicia in response to the detection of the object proximate the housing.

10. An electronic circuit for mounting to an inside surface of a windshield of a vehicle and configured to control a vehicle accessory, the circuit comprising:
a capacitive sensor configured to detect an object in proximity thereto;
a sensor guard disposed between the windshield and the capacitive sensor; and
a processor in communication with the capacitive sensor, wherein the sensor guard is configured to limit a false detection by the processor due to an input originating from an outside surface of the windshield.

11. The electronic circuit according to claim 10, wherein the input originating from the outside of the windshield corresponds to at least one of rain, snow, a wiper blade, and a biological material proximate the windshield.

12. The electronic circuit according to claim 10, wherein the sensor guard corresponds to a ground plane.

13. The electronic circuit according to claim 12, wherein the ground plane comprises a plurality of perforations configured to control a sensitivity of the capacitive sensor in a desired direction directed toward an interior of the vehicle.

14. The electronic circuit according to claim 10, wherein the sensor guard corresponds to a guard electrode.

15. The electronic circuit according to claim 14, wherein the guard electrode corresponds to an actively driven guard electrode in communication with the processor.

16. The electronic circuit according to claim 15, wherein the capacitive sensor is configured to output a voltage signal to the controller in response to the detection of the object.

17. The electronic circuit according to claim 16, wherein the processor is configured to drive the actively driven guard electrode in response to the voltage signal.

18. The electronic circuit according to claim 16, wherein the processor is configured to drive the actively driven guard electrode by outputting a signal that significantly matches the voltage signal.

19. A trainable transmitter module for a vehicle, comprising:
a housing configured for mounting to an inside surface of a windshield of the vehicle; and
an electronic circuit enclosed in the housing, the electronic circuit comprising:
a user interface including a capacitive touch switch having a touch electrode for sensing proximity of a user's finger or hand, and a guard electrode positioned between the windshield and at least a portion of the touch electrode, the guard electrode is configured to reduce a possibility that the touch electrode is falsely triggered by an input originating from an outside surface of the windshield;
a backlight for illuminating indicia on the user interface;
a processor coupled to the touch electrode, the guard electrode, and the backlight, the processor is configured to detect a voltage change on the touch electrode caused by proximity of the user's finger or hand and to activate the backlight in response to the voltage change on the touch electrode;
trainable transmitter circuitry coupled to the processor; and
wherein the processor is configured to control the trainable transmitter circuitry in response to user activation through the user interface.

20. The trainable transmitter module according to claim 19, wherein the processor is further configured to drive the guard electrode to significantly match the voltage change detected on the touch electrode.
